(19) United States
(12) Patent Application Publication
(10) Pub. No.: US 2012/0322198 A1
(43) Pub. Date: Dec. 20, 2012

(54) METHODS FOR SUBLIMATION OF Mg AND INCORPORATION INTO CdTe FILMS TO FORM TERNARY COMPOSITIONS

(76) Inventors: Pavel S. Kobyakov, Fort Collins, CO (US); W. S. Sampath, Fort Collins, CO (US); Kevin E. Walters, Milliken, CO (US); Jason M. Kephart, Fort Collins, CO (US); Keegan Barricklow, Fort Collins, CO (US)

(21) Appl. No.: 13/526,383

(22) Filed: Jun. 18, 2012

Related U.S. Application Data
(60) Provisional application No. 61/498,120, filed on Jun. 17, 2011.

(51) Int. Cl. H01L 31/18

(52) U.S. Cl. 438/95; 257/E31.015

(57) ABSTRACT

A method for sublimating a thin film of Magnesium (Mg) on a semiconductor structure for improved efficiency is described. One embodiment includes a method comprised of providing a semiconductor substrate in a vacuum chamber, wherein the substrate comprises a window layer and an absorber layer made of CdTe. The method further includes heating the substrate to a diffusion temperature or greater followed by depositing a Mg film on the absorber layer using a sublimation process, wherein at least a portion of the Mg forms a Cd₁₋ₓMgₓTe alloy within the absorber layer.

### CROSS REFERENCE TO RELATED APPLICATIONS

This application claims the benefit of U.S. Provisional Patent Application No. 61/498,120, filed Jun. 17, 2011, entitled “Sublimation Method to Make Cd₁₋ₓMgₓTe Alloys and CdS/CdTe/Cd₁₋ₓMgₓTe Electron Reflector Structures for Photovoltaic Cells,” which is hereby incorporated herein by reference in its entirety.

### GOVERNMENT LICENSE RIGHTS

This invention was made with government support under Grant No. IIP0968987 awarded by the National Science Foundation. The government has certain rights in the invention.

### FIELD OF THE INVENTION

The present invention relates to the treatment of thin film solar cells to improve efficiency. In particular, but not by way of limitation, the present invention relates to methods for sublimation of Magnesium (Mg) and incorporation into CdTe films in CdS/CdTe solar cells to improve efficiency

### BACKGROUND OF THE INVENTION

A solar cell (also referred to as a photovoltaic cell) is a semiconductor p-n junction diode, normally without an external bias, that is capable of converting light into electricity by the photovoltaic effect. In application, solar cells can be interconnected as part of a photovoltaic module that can be used in various devices—from small indoor pocket calculators to large industrial solar arrays. The ability of a solar cell to convert sunlight into electricity makes photovoltaic modules a potential major energy source. In addition, due the ‘renewable’ nature of sunlight, the use of photovoltaic modules as an energy source has significant potential environmental benefits. However, in order to achieve these benefits, photovoltaic modules must be cost effective energy sources. The cost effectiveness of photovoltaic modules depends, in part, on the efficiency of the photovoltaic module. Although present devices are functional, they are not sufficiently efficient or otherwise satisfactory. Accordingly, a system and method are needed to address the shortfalls of present technology and improve the efficiency of a solar cell.

The basic structure of a typical solar cell can include: 1) a front substrate, such as glass or plastic; 2) a front electrical contact, such as an electrical contact grid or a coating of a transparent conductive oxide (TCO); 3) a semiconductor structure, which can be either a homostructure or heterostructure; 4) a back electrical contact; and 5) a back substrate, such as a glass plate or a plastic plate. In operation, sunlight passes through the front substrate, past the front electrical contact, and is absorbed by the semiconductor structure. During this absorption, photons from the sunlight are absorbed by electrons in the semiconductor structure. If the energy of a photon is sufficient (i.e., if the energy of the photon is equal to or greater than the band gap energy of the material in which the photon is absorbed), the electron is knocked loose creating an electron and a hole, sometimes referred to as an electron-hole pair. The electron and the hole are also referred to as charge carriers. Once knocked loose, the electron and the hole are able to flow in opposite directions through the semiconductor structure. While the direction of flow depends on the characteristics of the semiconductor structure, the electron and hole will flow in opposite directions towards either the front electrical contact or the back electrical contact.

Thin-film solar cells based on CdTe shows immense potential for terrestrial photovoltaic power generation. This is because CdS/CdTe thin-film solar cells have a large absorption coefficient and high theoretical efficiency. Thin-film polycrystalline CdTe/CdS solar cell efficiencies have exceeded 15% (which is 65% of their theoretical values) and module efficiencies greater than 10% have been demonstrated for widely differing CdTe deposition technologies. Moreover, large-area photovoltaic panels can be economically fabricated. Furthermore, the optoelectronic properties of CdTe provide an ideal match to the solar spectrum for high conversion efficiency thin film devices. These features potentially make the CdTe thin-film solar cell the leading alternative energy source. Furthermore, CdTe offers flexibility in device design in that it forms isostructural and isoelectric alloys with other group II-VI elements and compounds, thereby allowing the absorber layer band gap to be narrowed or widened for tandem cell and optical detector applications.

The recorded CdTe efficiency is 16.5%, which is much less than its theoretical maximum efficiency of 29%. This discrepancy is primarily because the open-circuit voltage V_{OC} of CdTe thin film solar cells is 850 mV and is well below what is expected for the CdTe absorber band gap (1.45 eV). One way to improve the efficiency of a CdS/CdTe solar cell is to incorporate complex CdTe alloys into the device architecture. The incorporation of complex CdTe alloys such as, for example, Cd₁₋ₓMgₓTe into the device architecture can be one strategy to improve the open-circuit voltage V_{OC} of solar cells, and thus a strong possibility to improve the efficiency of CdS/CdTe thin-film solar cells.

For example, tandem junction cells and electron-reflector concepts both require complex alloys that can tune the bandgap of CdTe. The electron-reflector structure aims to improve the V_{OC} of the device. The electron reflector is a slightly higher bandgap layer on the back surface of the CdTe that acts as a conduction band energy barrier. Theoretical calculations show that a conduction band barrier height of 0.2 eV can improve the V_{OC} by 200 mV and the absolute efficiency by 3% in a 2 μm CdTe device with typically attainable properties of 10¹⁴ cm⁻³ carrier density and 1 nsec lifetime. On the other hand, tandem solar cells require higher bandgap materials for the top cell, which were successfully demonstrated with the use of complex CdTe alloys such as Cd₁₋ₓMgₓTe. Coincidentally, both applications require a Cd₁₋ₓMgₓTe alloy with approximately 1.7 eV bandgap (x ˜0.15).

Cd₁₋ₓMgₓTe thin films have been deposited using several techniques, including sputtering and co-evaporation. However, neither technique is appropriate for cost-effective manufacturing due to lack of processing speed and ability to deposit over large areas. Accordingly, a need exists for methods of cost effective manufacturing of Cd₁₋ₓMgₓTe thin films on the CdTe absorber layer in CdS/CdTe solar cells with high processing speed and the ability to deposit over large areas.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The present invention provides a method for fabricating a device structure for thin film solar cells with increased efficiency. In one exemplary embodiment, the present invention can include the steps of depositing a Mg film via a sublimation process onto a CdTe layer of a CdS/CdTe solar cell and allowing the Mg to react with the underlying layer to form the complex alloy Cd₁₋ₓMgₓTe. Formation of the CdTe layer can be accomplished by any number of methods known to those skilled in the art. Although the method selected to form the CdTe layer may somewhat influence the degree of Mg incorporation (because of differences in grain size and orientation of polycrystalline CdTe layers formed), any method is suitable since in all cases the Mg should react with CdTe and form the Cd₁₋ₓMgₓTe alloy. Any differences in CdTe films can be straightforwardly adjusted for by those skilled in the art using the adjustable parameters described herein. This is also true if using single crystal CdTe.

The methods described in the present invention have the advantages of being a cost effective method for manufacturing of Cd₁₋ₓMgₓTe thin films on the CdTe absorber layer in CdS/CdTe solar cells with high processing speed and the ability to deposit over large areas, and producing CdS/CdTe solar cells with high efficiency.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying drawings wherein:

FIG. 1 is a schematic of layer configuration and material compositions of CdS/CdTe solar cells modified by the sublimation of Mg.

FIG. 2 is showing a general approach to increase the efficiency of a semiconductor structure (of a known design).

FIG. 3 is an exemplary flow chart showing a specific method to increase the efficiency of a semiconductor structure with an absorber layer comprising CdTe.

FIG. 4 is an exemplary flow chart showing a specific method to increase the efficiency of CdS/CdTe solar cells.

FIG. 5 is a flow chart showing a method to sublimate Mg on the CdTe layer of a CdS/CdTe solar cell such that Mg forms a Cd₁₋ₓMgₓTe alloy within the CdTe layer.

FIG. 6 is an SEM cross-section image of a CdS/CdTe device with Mg deposited onto the back surface. The intermixed Cd₁₋ₓMgₓTe film is estimated to be 400 nm thick.

FIG. 7 is a spectroscopic ellipsometry spectrum of a CdS/CdTe/Mg stack (dashed) compared to a model fit of CdS/CdTe/Cd_{0.7}Mg_{0.3}Te (solid).

### DETAILED DESCRIPTION

The present invention provides a device structure for solar cells (also referred to as photovoltaic cells). The present invention also provides a method for fabrication of such solar cells.

In one aspect, the present invention provides a device structure with a layer of a complex Mg based CdTe alloy situated between the absorber layer (CdTe) and the back electrical contact which can be comprised of Mo, Ni, Au, Cu, W and/or the like. The Mg can be deposited on the absorber layer by sublimation and the back contact layer can be deposited by any method known in the art, such as, for example, vapor deposition or sputtering.

In one embodiment the present invention provides a solar (photovoltaic) cell comprising: 1) a front substrate, such as glass or plastic; 2) a front electrical contact, such as an electrical contact grid or a coating of a transparent conductive oxide (TCO); a semiconductor structure, which can be either a homostructure or heterostructure and comprising of: 3) a layer of n-type semiconductor which constitutes the window layer such as, for example, CdS, CdZnS, ZnS, or other n-type semiconductor materials; 4) a layer of p-type semiconductor which constitutes the absorber layer such as, for example, CdTe; 5) a thin film of Cd₁₋ₓMgₓTe alloy; 6) a back electrical contact; and 7) a back substrate, such as a glass plate or a plastic plate.

For example, in general, a basic CdS/CdTe solar cell of the present invention comprises a layer of n-type semiconductor (e.g., CdS) and a layer of p-type semiconductor (e.g., CdTe). Sandwiching these two layers are the front electrical contact, which is in contact with the n-type semiconductor, and a back electrical contact, which is in contact with the p-type semiconductor. These layers are formed on a transparent substrate. Thus, in one embodiment, the present invention provides a CdS/CdTe photovoltaic cell with a device structure comprising, in sequence: a) a transparent substrate, b) a front electrical contact, c) a layer of n-CdS, d) a layer of p-CdTe, e) a layer of Cd₁₋ₓMgₓTe alloy, f) a back electrical contact and g) a back transparent substrate.

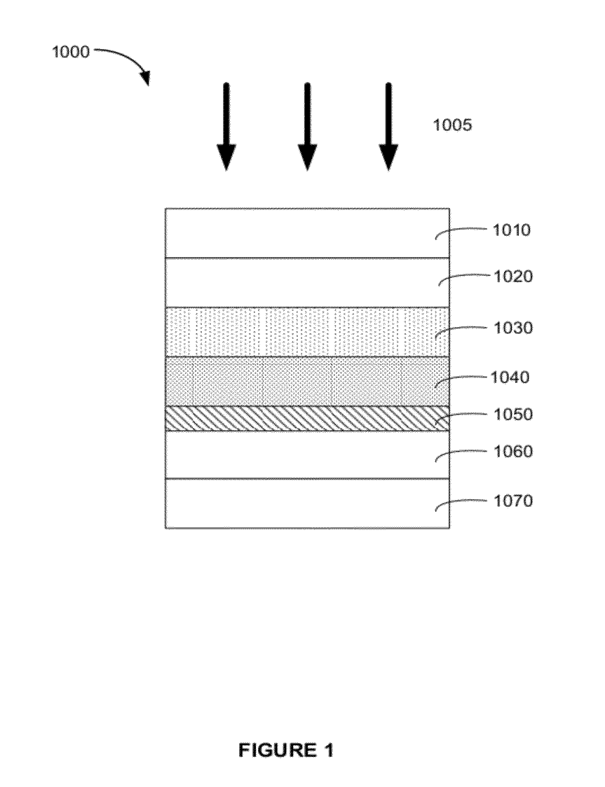

FIG. 1 is a graphical representation of the layer configuration and material compositions of CdS/CdTe solar cells modified by sublimation of Mg of the present invention. The front substrate 1010 of the CdS/CdTe photovoltaic cell depicted graphically in FIG. 1 is in direct contact with the front electrical contact 1020, and the illuminating light 1005 directly impinges on the solar cell through the substrate 1010. Typically around 2-4 mm thick, the front substrate 1010 protects the active layers of the solar cell from the environment, and provides the majority of the device's mechanical strength. The outer face of the front substrate 1010 often has an anti-reflective coating to enhance its optical properties. Thus, the front substrate 1010 is necessarily transparent or semi-transparent. By semi-transparent, it is meant that the front substrate 1010 transmits 50% or greater of light in the solar radiation range, i.e., 400 nm to 1400 nm. The optical transmission of the glass substrate is usually better than 95% over the wavelength region from 400 nm to 1000 nm. Typically, a thin glass is used as the front substrate 1010 because it is transparent, strong and cheap and can also endure the process temperature for the photovoltaic cell fabrication, which is typically in excess of 500° C. Any substrate which is transparent or semi-transparent and is an insulator that meets the requisite processing requirements can be used to fabricate the front substrate 1010. However, soda-lime glass is widely used to make this layer because of its low cost.

In some instances, the front electrical contact 1020 can be in direct contact with the front substrate 1010. In other instances, one or multiple buffer layers can be present between the front electrical contact 1020 and the front substrate 1010 (not shown in FIG. 1). The buffer layer(s) can act as sodium diffusion barrier(s) and can promote lattice matching between the front electrical contact 1020 and the front substrate 1010. The buffer layer(s) can be made of, for example, silicon-dioxide, silica, tin-dioxide, and so forth. The front electrical contact 1020 is typically a transparent conducting oxide (TCO) layer, but any transparent conducting material with the necessary properties (e.g., conductivity and transparency) can be used. The TCO layer is needed to reduce the series resistance of the solar cell, which would otherwise arise from the thinness of the CdS layer. It is preferable that the front electrical contact 1020 have an optical transmission of better than 90% over the wavelength region from 400 nm to 1000 nm. The TCO layer can be deposited on top of a glass substrate 1010 by a physical deposition method such as, for example, sputtering. For example, fluorine doped tin oxide, SnO₂:F, can be used as a front electrical contact 1020. It is preferable to use fluorine doped tin oxide due to its high electrical conductivity and high temperature tolerance. With SnO₂:F as the TCO, the thickness range of the front electrode layer 1020 can be typically between 100 nm and 1000 nm. Other examples of TCO materials include, but are not limited to, indium tin oxide (ITO), aluminum-doped zinc oxide (ZnO:Al), and other mixed oxides such as aluminum doped zinc gallium oxide.

Some embodiments of CdS/CdTe solar cells can include a front buffer layer comprising a semi-insulating, wide-bandgap material (not shown in FIG. 1). The front buffer layer can be in contact with front electrical contact 1020 (e.g., front buffer layer can be deposited on top of the TCO layer 1020 in FIG. 1). The primary function of this buffer layer is to minimize the probability of direct contact between the front electrical contact, e.g., TCO layer 1020, and the p-semiconductor layer, e.g., CdTe layer 1040, via the n-type semiconductor layer, e.g., CdS layer 1030. This layer is typically less than 100 nm in thickness, and is largely transparent. Typically, this buffer layer, for example an undoped SₙOₓ, can be deposited using physical vapor deposition, such as sputtering. Other suitable front buffer layer materials include, but are not limited to, zinc stannate (Zn₂SₙO₄), indium oxide (In₂O₃) and zinc oxide (ZnO). However, this buffer layer is optional in the construction of solar cells, and functional solar cells can be made without this buffer layer.

An n-type semiconductor layer 1030, whose primary function is to form a heterojunction with the p-type semiconductor layer, e.g. CdTe layer 1040, is in contact with front electrical contact 1020 (or the front buffer layer). Any n-type semiconductor material with the appropriate band gap can be used. The n-type semiconductor should have a band gap greater than that of the p-type semiconductor layer. Also, the band gap should be such that the n-type semiconductor layer 1030 does not absorb the incident illuminating light 1005. In this invention, a polycrystalline cadmium sulfide (CdS) layer is n-type doped layer, and therefore provides one half of the p-n junction. Being a wide band gap material (Eg ˜2.4 eV at 300K) it is transparent down to wavelengths of around 515 nm, and so is referred to as the window layer. The typical thickness of the n-type semiconductor layer, e.g., the CdS layer 1030, is about 100 nm or less. The thickness of the n-type semiconductor layer 1030 is usually kept as low as possible to permit maximum light transmission in this layer and therefore maximum light absorption in the n-type/p-type (e.g., CdS/CdTe) heterojunction region and in the bulk of the p-type (e.g., CdTe layer 1040), where charge generation takes place.

In some embodiments, the n-type semiconductor is cadmium sulfide or an alloy of cadmium sulfide (CdS). For example, a cadmium sulfide alloy can be formed by at least partially replacing the cadmium with Zn, Mg, Mn, or the like. As another example, a cadmium sulfide alloy can also be formed by at least partially replacing the sulfide with Te, Se, 0, or the like.

For example, in FIG. 1, the n-type semiconductor layer is a CdS layer 1030 and it is deposited on top of the front electrical contact 1020. The n-type semiconductor layer, e.g., CdS layer, can be deposited by a variety of methods known to those skilled in the art such as, for example, physical vapor deposition (PVD), chemical vapor deposition (CVD), chemical bath deposition, sputtering, close-space sublimation (CSS), and/or the like. When CdS is used as the n-type semiconductor layer, which has a bandgap of 2.42 eV, light with a wavelength shorter than 500 nm will be appreciably absorbed by this layer. Other n-type II-VI semiconductors with a wider bandgap, such as, for example (but not limited to), ZnO, ZnS, ZnSe and Cd₁₋ₓZnₓS, and/or the like can also be used as the n-type semiconductor. It is preferable to use n-type and p-type semiconductors that have relatively good lattice match. Hence, in this invention, CdS is the preferred material when CdTe is the p-type semiconductor because it has a good lattice match with CdTe.

A p-type semiconductor layer 1040 is in contact with the n-type semiconductor layer 1030 forming a p-n heterojunction. The function of the p-type semiconductor layer 1040 (e.g., CdTe layer) is to form a p-n heterojunction structure (e.g., CdS/CdTe structure) with the n-type semiconductor layer 1030 (e.g., CdS layer), and to serve as the active absorber layer in the solar cell for capturing sunlight. The p-type semiconductor layer 1040 can be any II-VI semiconductor such as, for example, CdTe, ZnTe, Cd₁₋ₓZnₓTe, Cd₁₋ₓHgₓTe, Cd₁₋ₓMgxTe, Cd₁₋ₓMnₓTe, Cu(In,Ga)Se₂, Cu(In,Al)S₂ and/or the like. It is preferable that the p-type semiconductor has a bandgap energy which matches (or at least overlaps significantly) with the wavelengths of the illuminating light 1005.

For example, in this invention, the p-type semiconductor layer 1040 is a cadmium telluride (CdTe) layer. CdTe is a preferred p-type semiconductor because it has a bandgap which matches the energy profile of solar radiation. The CdTe layer 1040 is, like the CdS, polycrystalline, but is p-type doped. Its energy gap (1.5 eV) is ideally suited to the solar spectrum, and it has a high absorption coefficient for energies above this value. It acts as an efficient absorber and is used as the p side of the p-n junction. Because it is less highly doped than the n-CdS, the depletion region is mostly within the p-CdTe layer 1040. This is therefore the active region of the solar cell, where both the carrier generation and collection occur. The thickness of the CdTe layer 1040 is typically around 1-10 μm. In the fabrication of a CdS/CdTe solar (photovoltaic) cell, the p-CdTe layer 1040 can be deposited on top of the n-CdS layer 1030 by any of the methods known in the art such as, for example, physical vapor deposition (PVD), chemical vapor deposition (CVD), vapor transport deposition (VTD), close-space sublimation (CSS), electrodeposition, and/or the like.

In some instances various post-deposition treatments can be applied to further improve the performance of CdS/CdTe photovoltaic cells. For example, in some instances a CdCl₂ treatment can, optionally, be applied after CdTe deposition. Such treatments can, for example, improve the film crystallinity, increase the grain size, introduce shallow dopants, and reduce lattice mismatch between CdS and CdTe. Furthermore, in some instances after CdCl₂ treatment, it might be necessary to remove residual CdCl₂ and other surface contaminants, e.g., by thermally annealing the CdS/CdTe film in vacuum or by cleaning with deionized water.

The p-type semiconductor CdTe layer is followed by a ternary layer of a complex CdTe alloy in the device architecture 1050. In this invention, the ternary layer is a Mg based alloy of CdTe that is formed by partially replacing Cd with Mg. The ternary layer 1050 is formed by depositing a Mg film via a sublimation process onto a binary CdTe layer and allowing the Mg to react with the underlying layer to form Cd₁₋ₓMgₓTe.

There are no requirements of maximum CdTe layer 1040 thickness to form an appropriate ternary Cd₁₋ₓMgₓTe layer 1050. The thickness of the CdTe layer 1040 can range from 1-2 μm, and the thickness of the desired ternary Cd₁₋ₓMgₓTe layer 1050 can range from 10-500 nm. The thickness of the desired ternary Cd₁₋ₓMgₓTe layer 1050 is dependent on the processes conditions such as, for example, deposition time, source temperature, pressure, and time the sample is held at high temperature, and/or the like. This is because the degree of Mg incorporation into the CdTe layer 1040 (i.e. how deep Mg penetrates into the CdTe and the exact ternary composition) is dependent on these setpoints.

The back electrical contact 1060 is in contact with the ternary Cd₁₋ₓMgₓTe layer 1050. The back electrical contact 1060 can be deposited by any of the methods known in the art such as, for example, sputtering, e-beam deposition, resistive heating, and/or the like. Generally, after deposition of the back electrical contact layer 1060, further annealing steps may or may not be necessary to produce an ohmic back contact. There is no limitation on the thickness or optical transparency of the back electrical contact layer 1060. The back electrical contact layer 1060 thickness is typically greater than 200 nm, which provides adequate conductivity. Most metals can be used, including, for example, common metals such as Cu, Ag, Au, Al, Ni, Fe, and Mo, and metal alloys such as stainless steel and those including the aforementioned common metals

In some embodiments, the CdS/CdTe solar cell can be a back-contact solar cell device whereby both the electrical contacts 1020 and 1060 reside on the rear of the solar cell. In such embodiments, electron-hole pairs generated by light that is absorbed at the front surface of the device can still be collected at the rear of the cell. Such embodiments are especially useful in concentrator applications where the effect of cell series resistance is greater. An additional benefit is that solar cells with both contacts 1020 and 1060 on the rear are easier to interconnect and can be placed closer together in the photovoltaic module since there is no need for a space between the cells. Furthermore, such back-contact solar cells can have higher efficiency than front-contact solar cells due to reduced shading on the front of the cell.

The back substrate 1070 of the CdS/CdTe solar cell is in direct contact with the back electrical contact layer 1060 and can be identical in structure and composition to the front substrate 1010. The back substrate 1070 can serve to protect the active layers of the solar cell from the environment, and can provide mechanical strength and stability to the device. The back substrate 1070 can be typically around 2-4 mm thick, and can either be transparent or semi-transparent. Similar to the front substrate 1010, the back substrate 1070 can be made of any material which is transparent or semitransparent such as, for example, glass, plastic and/or the like.

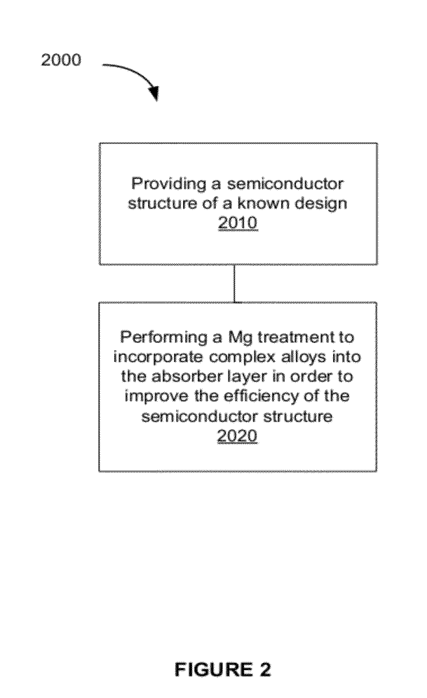

FIG. 2 is a flow chart illustrating a general approach to increase the efficiency of a semiconductor structure, according to an embodiment. The approach 2000 includes providing a semiconductor structure of a known design, at 2010. The semiconductor structure can be, for example, any type of a thin film solar cell with a p-n heterojunction where the absorber layer is p-type CdTe, including devices of the type X/CdTe, where X can be CdS, CdZnS, ZnS, or any other n-type semiconductor material. As discussed above, the X/CdTe solar cell can be a front-contact solar cell or a back-contact solar cell.

The approach 2000 includes performing a Mg treatment to incorporate complex alloys into the absorber layer in order to improve the efficiency of the semiconductor structure, at 2020. The efficiency of a semiconductor structure such as a solar cell is the ratio of the electrical power the solar cell delivers to an external load, to the optical (or illumination) power incident on the solar cell. The efficiency of a solar cell can be related to various factors including the open-circuit voltage V_{OC} of the solar cell which is at least in part, dependent on properties of the semiconductor structure. Theoretical calculations have shown that a conduction band barrier height of 0.2 eV can improve the V_{OC} by 200 mV and the absolute efficiency by 3% in a 1-2 μm CdTe device with typically attainable properties of 10¹⁴ cm⁻³ carrier density and 1 nsec lifetime. The Mg treatment can include depositing Mg on the semiconductor absorber layer by any number of methods known to those skilled in the art such as, for example, sputtering, co-evaporation, sublimation, and/or the like.

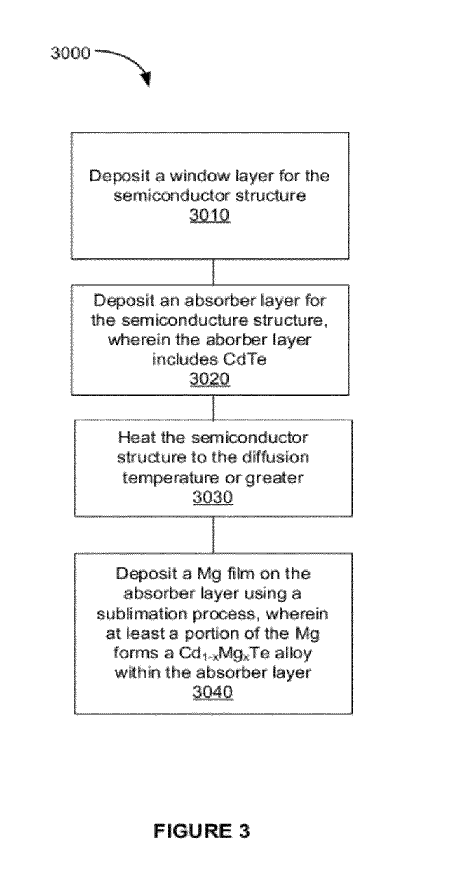

FIG. 3 is an exemplary flow chart showing a specific method to increase the efficiency of a semiconductor structure with an absorber layer comprising CdTe. The method 3000 includes depositing a window layer for the semiconductor structure, at 3010. As discussed above, the window layer can be any type of n-doped semiconductor material that can have a good lattice match with CdTe such as, for example, CdS, CdZnS, ZnS, and/or the like.

The method 3000 includes depositing an absorber layer for the semiconductor structure, wherein the absorber layer includes CdTe, at 3020. As described above, the CdTe absorber layer can be deposited by any of the methods known in the art such as, for example, sputtering, physical vapor deposition (PVD), chemical vapor deposition (CVD), vapor transport deposition (VTD), close-space sublimation (CSS), electrodeposition, and/or the like. The CdTe layer can be of purity levels that are generally consistent with current practices in industry and research.

Although the method selected to form the CdTe layer may somewhat influence the degree of Mg incorporation (due to differences in grain size and orientation of the polycrystalline CdTe layers formed), any method is suitable since in all cases the Mg should react with CdTe and form the complex alloy. Any differences in CdTe films can be straightforwardly adjusted for by those skilled in the art using the adjustable parameters described herein. This is also true if using single crystal CdTe.

The method 3000 includes heating the semiconductor structure to the diffusion temperature or greater, at 3030. In instances where sublimation is used to deposit Mg on the CdTe absorber layer, in order to form an alloy with the CdTe absorber layer, the semiconductor substrate (solar cell) must be heated to the diffusion temperature or greater wherein, the diffusion temperature is the temperature at which Mg will effectively diffuse into the CdTe absorber layer. This temperature will depend on many variables, including, the structure and composition of the CdTe absorber layer, the method used to form the CdTe absorber layer, etc.

The semiconductor substrate temperature in concert with the Mg source temp and operating pressure controls the amount of Mg that gets deposited on the CdTe layer. The semiconductor substrate temperature also controls the Mg diffusion into the CdTe absorber layer when coupled with the time the substrate is at the diffusion temperature or higher both during and post deposition. For most applications, this elevated substrate temperature is preferred to be between 200 and 500° C. Lower substrate temperature tends to deposit more Mg metal film, while higher substrate temperatures deposits less Mg, and the amount of Mg that does deposit tends to diffuse through the CdTe film more rapidly which can adversely affect the absorbing properties of the CdTe layer.

The method 3000 further includes depositing a Mg film on the absorber layer using a sublimation process, wherein at least a portion of the Mg forms a Cd₁₋ₓMgₓTe alloy within the absorber layer, at 3040. Cd₁₋ₓMgₓTe thin films can be deposited by other methods known in the art such as, for example, sputtering and co-evaporation. However, these methods are not appropriate for cost-effective manufacturing due to lack of processing speed and ability to deposit over large areas. The sublimation process involves heating Mg under high temperature and low pressure to form Mg vapor which deposits on the CdTe layer. Typically, the higher the temperature of the Mg source, the more the Mg flux is generated. The Mg flux coupled with the semiconductor substrate temperature and pressure can determine the deposition rate of Mg. At an operating pressure of 40 mTorr, an optimal Mg source temperature is between the about 380 and 550° C.

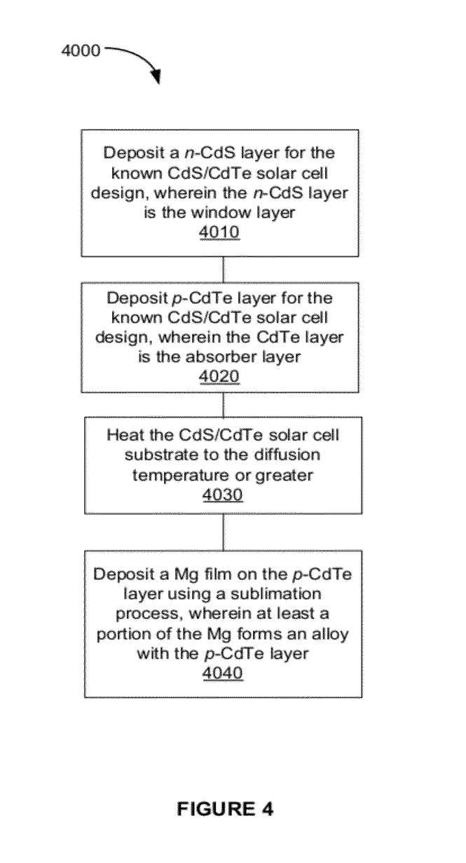

FIG. 4 is an exemplary flow chart showing a specific method to increase the efficiency of CdS/CdTe solar cells. The method 4000 includes depositing a n-CdS layer for the known CdS/CdTe solar cell design, wherein the n-CdS layer is the window layer, at 4010. The n-CdS window layer can be deposited by any number of methods known to those skilled in the art such as, for example, physical vapor deposition (PVD), chemical vapor deposition (CVD), chemical bath deposition (CBD), chemical surface deposition (CSD), sputtering, close-space sublimation (CSS), and/or the like.

One of the purpose of the n-CdS window layer is to keep the p-n junction away from TCO interface which typically has large surface recombination. However, the part of the solar spectrum that is absorbed in CdS window layer does not contribute to the generation of photocurrent, leading to a loss of efficiency. To minimize this loss of current, the thickness of CdS window layer needs to be as low as possible. Controlling the CdS thickness uniformity at the manufacturing scale requires control over the CdS deposition and CdS-CdTe interdiffusion during post-deposition processing. Deposition methods showing promise for controlling CdS film thickness <100 nm are chemical bath deposition (CBD) and chemical surface deposition (CSD), with the latter method giving very high chemical utilization of dissolved Cd species

The method 4000 includes depositing a p-CdTe layer for the known CdS/CdTe solar cell design, wherein the CdTe layer is the absorber layer, at 4020. As discussed above, the p-CdTe layer can be deposited by any of the methods known in the art such as, for example, physical vapor deposition (PVD), chemical vapor deposition (CVD), vapor transport deposition (VTD), close-space sublimation (CSS), electrodeposition, and/or the like. Close-space sublimation is preferred because it is capable of depositing a crystalline CdTe film at very high deposition rates. To produce a p-type CdTe film using the close-space sublimation method, it is necessary to use oxygen as a carrier gas as the oxygen carrier gas is considered to act as p-type dopant in CdTe. In other instances, oxygen can also be used after the sublimation process to dope the CdTe layer.

The method 4000 includes heating the CdS/CdTe solar cell substrate to the diffusion temperature or greater, at 4030. The diffusion temperature is the temperature at which Mg will effectively diffuse into the CdTe layer which can then allow the Mg to form an alloy with the CdTe. This temperature will depend on many variables, including operating pressure, the structure and composition of the CdTe layer, the method used to form the CdTe layer, etc.

The method 4000 further includes deposit a Mg film on the p-CdTe layer using a sublimation process, wherein at least a portion of the Mg forms an alloy with the p-CdTe layer, at 4040. The reaction between the Mg metal and the CdS/CdTe substrate film can form complex alloys. For example, the deposition of Mg onto CdTe can lead to the formation of MgTe, or a CdMgTe alloy, through the following reaction:

Mg+CdTe→MgTe+Cd (1)

whereby the free energy of formation for Eq.1 can be calculated with free energy of formations of CdTe and MgTe:

Cd+Te→CdTe (2)

Mg+Te→MgTe (3)

whereby the room temperature free energy of formation for equation 2 and 3 are calculated to be −99.4 KJ/mol and −207 KJ/mol respectively. This can lead to the calculation of the free energy of formation for equation 1 to be −107.6 KJ/mol, indicating the reaction is favorable to the right side of the equation. Hence Mg is thermodynamically favored to displace some of the Cd from the CdTe absorber layer to form a complex CdMgTe alloy such as, for example, Cd₁₋ₓMgₓTe.

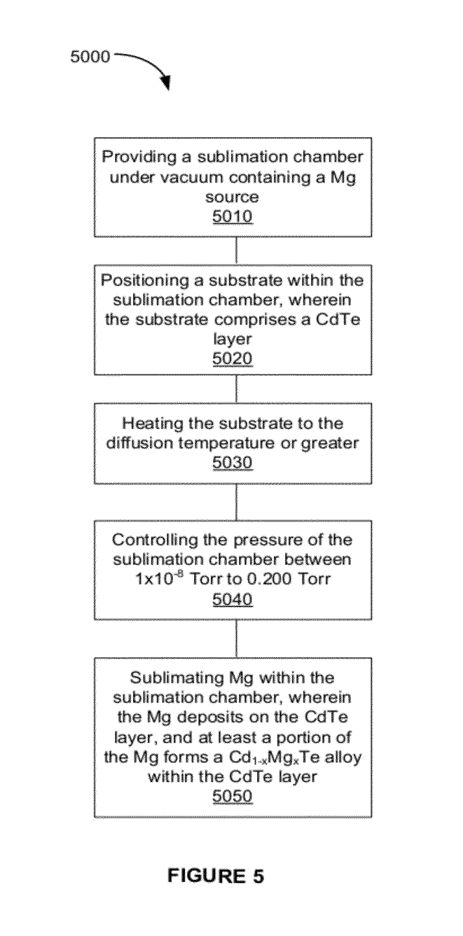

FIG. 5 is a flow chart showing a method to sublimate Mg on the CdTe layer of a CdS/CdTe solar cell such that Mg forms a Cd₁₋ₓMgₓTe alloy within the CdTe layer. The method 5000 includes providing a sublimation chamber under vacuum containing a Mg source, at 5010. In some embodiments, the Mg source can be a heated graphite crucible loaded with evaporation grade Mg pellets. In other embodiments, those skilled in the art will be able to sublimate the Mg on the CdS/CdTe substrate using a variety of heating, vacuum, storage, and deposition devices (e.g. a deposition crucible).

The method 5000 includes positioning a substrate within the sublimation chamber, wherein the substrate comprises a CdTe layer, at 5020. In some embodiments, the sublimation of Mg can take place inside dedicated custom built sublimation chambers, such as, for example, the Deposition Research Chamber (DRC), which is housed in the Materials Engineering Laboratory at Colorado State University. The DRC is outfitted with individual substrate motion levers to precisely control the position of the substrate inside the sublimation chamber, load lock, and two thermal stations: one for substrate heating and one for Mg deposition. The preferred ratio of the size of the Mg source crucible to the semiconductor substrate size is approximately 1:1, although other ratios may be used if the operator has sufficient hardware to deposit Mg uniformly onto the CdS/CdTe substrate at that ratio. Typically, a 1:1 ratio is sufficient as the source can be scaled up to large areas. The invention described herein may be practiced in a wide variety of physical configurations. For those skilled in the art, these parameters can be scaled to match the desired substrate size, deposition rate, Mg film uniformity, etc.

The method 5000 includes heating the substrate to the diffusion temperature or greater, at 5030. As discussed above, the diffusion temperature is the temperature at which Mg will effectively diffuse into the CdTe layer to form an alloy with the CdTe. The diffusion temperature will depend on many variables, including operating pressure, the structure and composition of the CdTe layer, the method used to form the CdTe layer, etc. Prior to Mg deposition, the sublimation chamber is preheated and purged several times with an inert gas such as, for example, Ar, N₂, or He to reduce the background oxygen and water content which can react with the Mg vapor/film.

The method 5000 includes controlling the pressure of the sublimation chamber between 1×10⁻⁸ Torr to 1 Torr, at 5040. The operating pressure inside the sublimation chamber can influence other parameters, but itself can be varied significantly. This can allow the user to adjust the operating pressure to match the process conditions of any other deposition processes occurring up or downstream from the Mg deposition (e.g. CdTe deposition). The deposition process of Mg and subsequent reaction can be performed at pressures as low as approximately 1×10⁻⁸ Torr or at least as high as approximately 1 Torr. Additionally, the minimum base pressure in the sublimation chamber should be maintained at 1×10⁻⁶ Torr. A variety of process gases such Ar, N₂, He and so forth can be used to control the operating pressure within the sublimation chamber. In embodiments of the present invention, the process gas can be varied to control the deposition and film qualities. Inert gasses, such as Ar, N₂, He and/or similar, as well as low background water vapor, have been found necessary beneficial for reducing oxygen incorporation. In other cases, oxidizing gasses or other gasses could be used to change the deposition characteristics and film properties, if desired. A large number of processing gasses, readily available and known to those skilled in the art, can be used to obtain desired film property changes. Although this parameter is not critical, lower base pressures will result in reduced oxygen and water content in the sublimation chamber.

The method 5000 further includes sublimating Mg within the sublimation chamber, wherein the Mg deposits on the CdTe layer, and at least a portion of the Mg forms a Cd₁₋ₓMgₓTe alloy within the CdTe layer, at 5050. As described above, the sublimation process involves heating Mg source under high temperature and low pressure to form Mg vapor which deposits on the CdTe layer. Typically, the higher the temperature of the Mg source, the more the Mg flux is generated. The Mg flux coupled with the semiconductor substrate temperature and pressure can determine the deposition rate of Mg. Additionally, the longer the deposition time of Mg, the more Mg is deposited on the CdS/CdTe substrate. The time scale for the deposition can be varied depending on the degree of Mg incorporation desired. For most photovoltaic applications, the time scale can vary between a few seconds to 30 minutes, with approximately 2 minutes being the preferred Mg deposition time.

After the deposition of Mg onto the CdS/CdTe substrate is complete, the substrate is cooled to room temperature under continuous Ar (or any other inert gas) flow. The rate of cooling will depend significantly on the degree of Mg incorporation desired. It is preferable to cool the substrate at a rate of about 100° C./minute, but faster cooling rates can be used to “freeze” the Mg in place or slower cooling rates can be employed to let any excess Mg diffuse farther into the CdTe layer underneath and react. Additionally, a thermal anneal step can be performed after the Mg deposition to allow the Mg to diffuse and react deeper into the CdTe film. This optional anneal can be performed in instances where excess Mg has been deposited.

An undesirable side-effect of depositing Mg films onto CdTe substrates is the formation of oxides on the back surface which leads to poor photocurrent generation and low V_{OC} from the solar cell device. This is because the oxides on the back surface may act as insulators and therefore increase the series resistance in the solar cell. Secondly, since the formed Cd₁₋ₓMgₓTe layer is graded (as will be discussed herein), a large hole barrier in the valence band is present in the device when x approaches unity. Hence an etching step can be implemented to remove the oxides formed on the back surface of the solar cell. The etching process may be accomplished using a number of techniques known to those skilled in the art. In some instances, the films can be etched with Br₂/methanol prior to metallization. However, other etching methods such as nitric/phosphoric etching or iodine/methanol etching may also be used. Non-chemical methods, such as ion etching inside the vacuum system can also be used. The parameters for the etching process are selected in each case and depends on the etching rate of the technique chosen and the desired depth of etching into the film. In the case of Br₂/methanol, etch times of less than one minute is generally sufficient. The etching process reduces both the insulative back surface oxides and the detrimental valence band hole barriers expected from Cd₁₋ₓMgₓTe with x>0.2.

In some instances, it is possible to add a CdCl₂ treatment step, which in photovoltaic devices is known to passivate the CdTe film and improve the voltage of the device and the current. The CdCl₂ treatment step may be inserted anywhere in the method described herein, including before Mg deposition, after Mg deposition, and after etching. In other instances, incorporation of a Cu doped absorber layer can also occur as it has been shown to be effective for CdTe films and potentially effective on CdMgTe films.

The final step involves the metallization of the device which deals with depositing the front and back electrical contacts on the solar cell via by any of the methods known in the art such as, for example, sputtering, e-beam deposition, resistive heating, and/or the like. Any number of highly conducting metals can be used to form the electrical contacts such as, for example, Cu, Ag, Au, Pb, Al, Ni, Fe, and Mo, and metal alloys such as stainless steel and those including the aforementioned common metals.

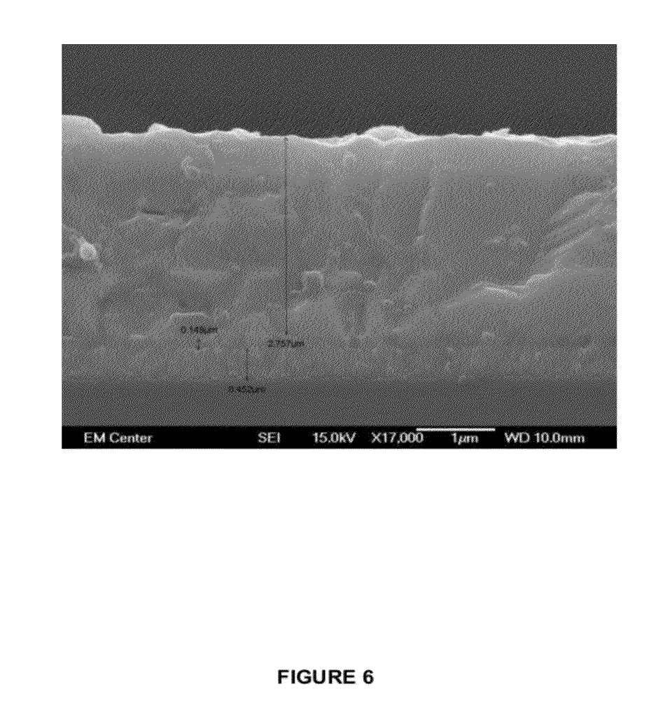

FIG. 6 is a Scanning Electron Microscope (SEM) cross-section image of a CdS/CdTe device with Mg deposited onto the back surface. Cross-sectional SEM imaging of Mg deposited on a CdCl₂ treated CdS/CdTe solar cell shows that a distinct Mg layer is not present. In fact, the Mg rich layer which comprises the intermixed Cd₁₋ₓM_{gx}Te film is estimated to be 400 nm thick and is graded which is indicative of gradual diffusion of Mg into the CdTe layer. Additionally, the intermixed Cd₁₋ₓM_{gx}Te film also retains the CdTe grain structure. This may be due to the small lattice mismatch between MgTe and CdTe (less than 1%). The even lower lattice mismatch of an alloyed Cd₁₋ₓMgₓTe film will require only a few monolayers to accommodate the strain.

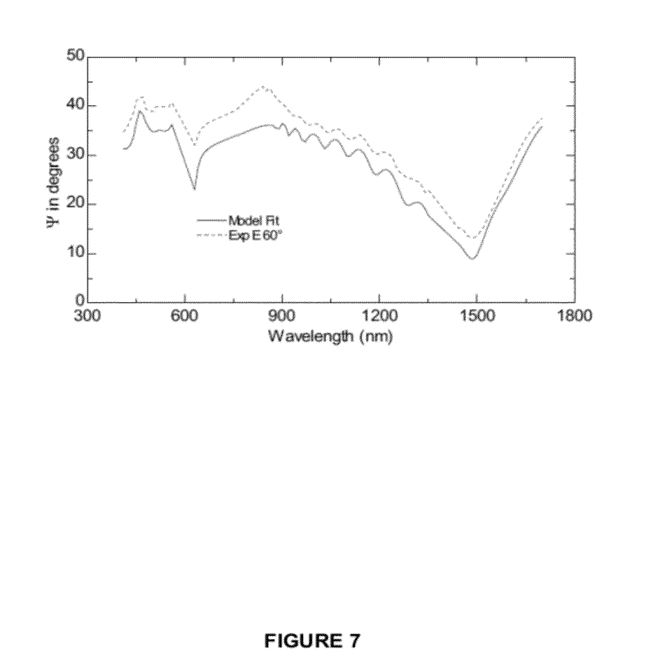

FIG. 7 shows the spectroscopic ellipsometry spectrum of a CdS/CdTe/Mg stack (dashed) that was imaged in FIG. 6 and compared to a model fit of CdS/CdTe/Cd_{0.7}Mg_{0.3}Te (solid). The spectroscopic ellipsometry was performed through the glass because the sample is rough and scatters light from the back surface. The model is for a layer of Cd_{0.7}Mg_{0.3}Te at the back of the CdS/CdTe stack with CdTe thickness of 2400 nm. This thickness of the Cd₁₋ₓMgₓTe film matches the estimated penetration of Mg into the CdTe film and thus the expected location of the CdTe/Cd₁₋ₓMgₓTe interface. The ripple pattern is produced due to reflections from the CdTe/Cd₁₋ₓMgₓTe interface and is not observed in CdS/CdTe/Mg metal ellipsometry models or in CdS/CdTe only spectra or models. FIGS. 7 and 8 indicate the possible formation of a layer of Cd₁₋ₓMgₓTe via the reaction of Mg with CdTe at the back of the CdS/CdTe stack.

In conclusion, the present invention provides, among other things, methods for sublimation of Magnesium (Mg) and incorporation into CdTe films in CdS/CdTe solar cells to improve efficiency. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A method for producing a semiconductor structure, the method comprising:
providing a substrate in a vacuum chamber, wherein the substrate comprises:
a window layer; and
an absorber layer, the absorber layer comprising CdTe;
heating the substrate;
depositing a Mg film on the absorber layer using a sublimation process, wherein at least a portion of the Mg forms a Cd₁₋ₓMgₓTe alloy within the absorber layer.

2. The method of claim 1, wherein heating the substrate comprises heating the substrate to a temperature of 200 degrees Celsius or greater.

3. The method of claim 1, further comprising preheating and purging the vacuum chamber before depositing the Mg film.

4. The method of claim 1, wherein heating the substrate comprises heating the substrate to a diffusion temperature or greater before depositing the Mg film.

5. The method of claim 1, wherein heating the substrate comprises heating the substrate to a temperature within the range of 200-500 degrees Celsius.

6. The method of claim 1, wherein heating the substrate comprises heating the substrate to a temperature within the range of 300-450 degrees Celsius.

7. The method of claim 1, wherein heating the substrate comprises heating the substrate to a temperature within the range of 370-390 degrees Celsius.

8. The method of claim 1, further comprising:
performing an oxide etch after depositing the Mg film; and
metallization of the substrate.

9. The method of claim 1, further comprising performing a CdCl₂ treatment.

10. The method of claim 9, wherein the CdCl₂ treatment is performed after depositing the Mg film.

11. The method of claim 1, further comprising doping the absorber layer with Cu.

12. A method for forming a semiconductor structure, the method comprising:
providing a sublimation chamber;
positioning a substrate within the sublimation chamber, wherein the substrate comprises a CdTe layer;
heating the substrate;
sublimating Mg within the sublimation chamber, wherein the Mg deposits on CdTe layer, wherein at least a portion of the Mg forms a Cd₁₋ₓMgₓTe alloy within the CdTe layer.

13. The method of claim 12, wherein the sublimation chamber includes a source, the method comprising:
maintaining a source temperature between 380-550 degrees Celsius while sublimating Mg.

14. The method of claim 12, wherein the sublimation chamber includes a source, the method comprising:
maintaining a source temperature between 420-440 degrees Celsius while sublimating Mg.

15. The method of claim 12, further comprising:
controlling the pressure of the sublimation chamber between 1×10⁻⁸ Torr to 1 Torr.

16. The method of claim 12, further comprising cooling the substrate at a rate of 100 degrees Celsius per minute or lower.

17. The method of claim 12, wherein heating the substrate comprises heating the substrate to a temperature within the range of 300-450 degrees Celsius.

18. The method of claim 12, further comprising:
performing an oxide etch after depositing the Mg film; and
metallization of the substrate.

19. The method of claim 12, further comprising performing a CdCl₂ treatment.

20. The method of claim 12, further comprising doping the absorber layer with Cu.
